(19) United States
(12) Patent Application Publication
(10) Pub. No.: US 2008/0129150 A1
(43) Pub. Date: Jun. 5, 2008

(54) HIGH TEMPERATURE SUSTAINABLE PIEZOELECTRIC SENSORS USING ETCHED OR MICROMACHINED PIEZOELECTRIC FILMS

(76) Inventor: Hongxi Zhang, San Juan Capistrano, CA (US)

Correspondence Address: HELLER EHRMAN LLP, 275 MIDDLEFIELD ROAD, MENLO PARK, CA, 94025-3506, US

(21) Appl. No.: 11/950,993

(22) Filed: Dec. 5, 2007

Related U.S. Application Data
(60) Provisional application No. 60/868,662, filed on Dec. 5, 2006.

(51) Int. Cl. H01L 41/08; G01P 15/09; H01L 41/053; H01L 41/113; H01L 41/16

(52) U.S. Cl. 310/329; 310/338; 310/354; 73/514.34

(57) ABSTRACT

The present invention is directed to sensors that use wide band gap piezoelectric films such as aluminum nitride and zinc oxide. The films can be deposited with chemical and physical methods and etched or micro machined into miniature and micro sensing elements. Various piezoelectric sensing structures such as compression mode and cantilever-type accelerometers, diaphragm-type pressure sensors, and micro sensor arrays can be manufactured with the sensing elements. They can be used in the measurements of vibration, shock, dynamic pressure, stress, and high resolution ultrasound non-destructive test at high temperature up to 800-1000° C.

### CROSS-REFERENCE TO RELATED APPLICATIONS

This application claims the benefit of U.S. Ser. No. 60/868,662, filed Dec. 5, 2006, which application is fully incorporated herein by reference.

### BACKGROUND OF THE INVENTION

1. Field of the Invention

The present invention relates generally to sensors, and more particularly to sensors with micromachined piezoelectric films.

2. Description of the Art

A piezoelectric material generates electrical charge in response to a stress, which is termed the piezoelectric effect. The amount of the electrical charge is generally proportional to the applied force and determined by the piezoelectric charge sensitivity, or piezoelectric coefficient. This electrical charge can be tested and used to measure the pressure, force, shock, and acceleration.

Piezoelectric sensors have been developed using materials such as quartz and lead zirconium titanate (PZT). However, the piezoelectric materials have not been suitable for use at high temperatures. The maximum operation temperature of the sensors made from such materials is limited by their phase transition temperature and Curie temperature (Tc). The operation temperatures of the existing sensors based on quartz and PZT are 150-200° C. The sensors based on bismuth titanate have an operation temperature of ˜450° C.

More and more engines and power platforms will operate at higher temperature to efficiently use the fuels and significant amount of design goes to isolating the sensors and the heat sources. Accordingly, there is a need for sensors with an extended temperature range that can be used to measure vibration and pressure.

The current accelerometers and pressure sensors that are made of piezoelectric ceramics and crystals are bulky and heavy. Miniature sensors based on films and micro fabrication technology can significantly increase their flexibility and performance and reduce the system load.

Piezoelectric ultrasound sensors are widely used in medical imaging systems and non-destructive evaluation (NDE). On-line engine health monitoring and high temperature manufacturing of precision mechanicals require ultrasound emitters and detector/sensors that can survive and operate in high-temperature harsh environments.

Wide band-gap piezoelectric materials like aluminum nitride, zinc oxide, and tantalum oxide show very good robustness at high temperature and have very high dielectric strength. Their piezoelectric characteristics enable the manufacture of piezoelectric sensors that can work at harsh environments. The films of aluminum nitride, zinc oxide, and tantalum oxide can be coated by reactive sputtering, chemical vapor deposition (CVD), and molecular beam epitaxy (MBE) on various substrates. By wet or dry etching and micromachining, miniature and micro sensing elements can be manufactured. Based on the elements, sensors can be developed for the measurements of vibration, shock, pressure, force, and stress at high temperatures.

With micro fabrication technology, sensing elements arrays can be manufactured. These arrays can be used to measure the stress distribution and high-resolution ultrasound monitoring of precision structures.

### SUMMARY OF THE INVENTION

One object of the present invention is to introduce wide band gap piezoelectric thin films such as aluminum nitride, zinc oxide, and tantalum oxide in the construction of piezoelectric sensors for dynamic measurements of acceleration, pressure, and force at high temperatures.

Another object of the present invention is a piezoelectric sensor comprising a housing, a diaphragm coupled to the housing, a substrate body coupled to the diaphragm, wherein the substrate body is coated with a wide band gap piezoelectric thin film, and a connector for electrically connecting the film-coated substrate body with test electronics.

Another object of the present invention is a piezoelectric pressure sensor comprising a housing, a diaphragm coupled to the housing, a substrate body coupled to the diaphragm, wherein the substrate body is coated with a wide band gap piezoelectric thin film, and a connector for electrically connecting the film-coated substrate body with test electronics; whereby a first electrode and a second electrode are coupled to the wide band gap piezoelectric thin film.

Another object of the present invention is a compression-mode piezoelectric acceleration sensor comprising a mass, a support structure, a substrate body coated with a wide band gap piezoelectric thin film mounted to the support with a support member, a first electrode and a second electrode coupled to the wide band gap piezoelectric thin film, a first insulator positioned to insulate the wide band gap piezoelectric thin film and the mass, and a second insulator positioned between the second electrode and the support member to isolate the wide band gap piezoelectric thin film and the crystal support.

Another object of the present invention is a cantilever-type piezoelectric acceleration sensor comprising a beam of metal coupled to a base and a clamp at one end and a mass loaded on another. A sensing element coated with wide band gap piezoelectric film and coupled to an electrode is positioned on the metal beam between the base and mass.

Another object of the present invention is a micro sensor array comprising a substrate coated with an electrode layer; a wide band gap piezoelectric film applied to the electrode layer; wherein the film is etched to manufacture multiple micro sensing elements, a top electrode coated on to the piezoelectric film; and a charge amplifier or voltimeter connected to the micro sensing elements.

Another object of the present invention is to fabricate a device by both chemical methods (like reactive sputtering and chemical vapor deposition) and physical techniques (such as sputtering and laser ablation) on various substrates such as silicon, sapphire, and stainless steels.

Another object of the present invention is to use wet or dry etching or micromachining on films of aluminum nitride, zinc oxide, and tantalum oxide to manufacture miniature structures and components.

Another object of the invention is to package the film components into conventional sensors units or made into sensors arrays. The sensor arrays can be used to measure the pressure and stress distributions in a structure. They can also be used as high resolution ultrasound imaging detector arrays for non-destructive evaluation.

Another object of the present invention is to construct sensors and sensor arrays that can work at high temperatures up to 800 to 1000° C.

Accordingly, there is a need for sensors with extended temperature range based on films and micro fabrication technology that can survive and operate in high temperature harsh environments.

### DESCRIPTION OF THE FIGURES AND DRAWINGS

FIG. 1 is an exploded diagram illustrated one embodiment of a sensor of the present invention.

FIG. 2 shows the schematic drawing of a pressure sensor based on the etched or micromachined AlN, ZnO, or Ta₂O₅ piezoelectric films that can work at very high temperatures.

FIG. 3 shows top and cross-sectional view of piezoelectric unimorph using AlN or ZnO film on metal diaphragm. The diameter of the top electrode is optimized to be 0.7 of that of the AlN or ZnO film.

FIG. 4 shows the schematic drawing of a compression-mode acceleration sensor subassembly of the present invention. based on the etched or micromachined AlN, ZnO, or Ta₂O₅ piezoelectric films that can work at very high temperatures.

FIG. 5 shows the frequency response of a compression-mode accelerometer made of piezoelectric AlN films.

FIG. 6 demonstrate the thermal response of the compression-mode accelerometer made of piezoelectric AlN films. The sensor can work at 800° C. (1472° F.).

FIG. 7 shows the schematic drawing of a cantilever-type or bending mode accelerometer based on the etched or micromachined AlN, ZnO, or Ta₂O₅ piezoelectric films that can work at very high temperatures.

FIG. 8 shows a schematic drawing of micro sensors and arrays based on etched or micro machined AlN, ZnO, or Ta₂O₅ piezoelectric films that can work at very high temperatures.

FIG. 9 is the XRD patterns of an aluminum nitride film coated on silicon by reactive ion sputtering method. The inset is the rocking curve of the (002) diffraction.

FIG. 10 is the SEM (scanning electron microscopy) of the cross-section an AlN film.

FIG. 11 shows the samples of etched AlN patterns or components arrays.

### DETAILED DESCRIPTION

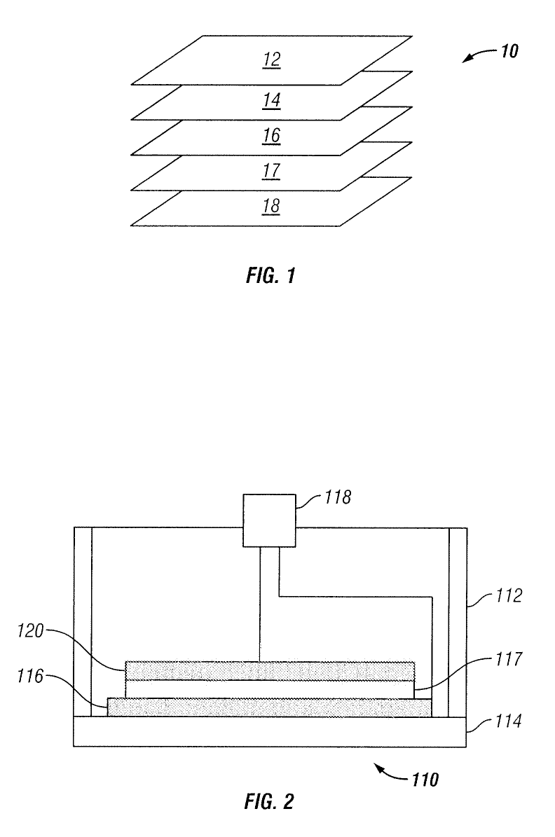

Referring to FIG. 1, one embodiment of the present invention is a piezoelectric sensor 10 which includes a housing 12 and a diaphragm 14 coupled to the housing 12. A substrate body 16 is coupled to the diaphragm. The substrate body being coated with a wide band gap piezoelectric thin film 17. A connector 18 electrically connects the ceramic body with test electronics.

In another embodiment of the present invention, the substrate is selected from the group consisting of silicon, sapphire, alumina ceramics, metals and alloys such as aluminum and stainless steels and Iconel.

In another embodiment of the present invention, the piezoelectric thin films are high-temperature-sustainable aluminum nitride (AlN), zinc oxide (ZnO), tantalum oxide (Ta₂O₅) and other piezoelectric materials.

The piezoelectric coefficients or charge sensitivity of the piezoelectric films are in the range of 1-10 μC/N depending on the substrates and deposition parameters. Their resistivity is up to 10¹³ Ω·cm. The typical piezoelectric coefficients for aluminum nitride (AIN), zinc oxide (ZnO), and tantalum oxide (Ta₂O₅) are 1-5 pC/N, 2-10 pC/N, and about 5 pC/N, respectively.

The piezoelectric films can be etched or micro machined by wet or dry etching processing. One of the etchants for aluminum nitride and zinc oxide films is a solution containing trimethyl ammonium hydroxide

Referring to FIG. 2, one embodiment of the present invention is a piezoelectric pressure sensor 110 which includes a housing 112 and a diaphragm 114 coupled to the housing 112. A substrate body 116 is coupled to the diaphragm. The substrate body being coated with a wide band gap piezoelectric thin film 117. A connector 118 electrically connects the top electrode 120 and bottom electrode/substrate 116 with test electronics.

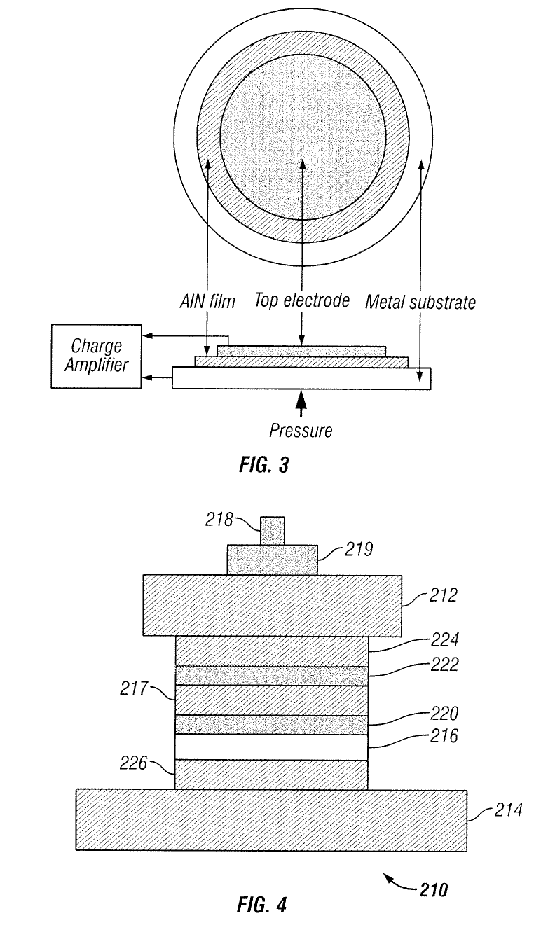

Another embodiment of the present invention is a unimorph built with etched or micromachined AlN, ZnO or Ta₂O₅ films on metal diaphragm (as substrate), as shown in FIG. 3. Electrical charge will be generated when a dynamic pressure is applied onto the backside of the substrate due to its deflection. The amount of the electrical charge is proportional to the deflection, while maximum charge can be obtained when the diameter of the top electrode is designed to be 0.7 of that of the film. The sensor can be used to measure the dynamic pressure in a combustion chamber at high temperature. Because no mass is loaded onto the film, vibration compensation is not needed, which significantly simplifies the packaging and reduce the sensor's volume and weight.

Referring now to FIG. 4, a sensor subassembly 210 includes a mass 212, a support structure 214 and a substrate body 216 coated with a wide band gap piezoelectric thin film 217. The piezoelectric thin film 217 comprises aluminum nitride (AIN), zinc oxide (ZnO), tantalum oxide (Ta₂O₅) or other piezoelectric materials. The substrate 216 can be silicon, sapphire, alumina ceramics, metals or alloys such as aluminum and stainless steels. The substrate body 216 is mounted at the support structure 214 with post 218 and nut 219. First and second electrodes 220 and 222 are coupled to the substrate body 216 and the piezoelectric film 217, respectively. A first insulator 224 is positioned between the second electrode 222 and the 212. A second insulator 216 is positioned to insulate the piezoelectric film 217 and the crystal support 214.

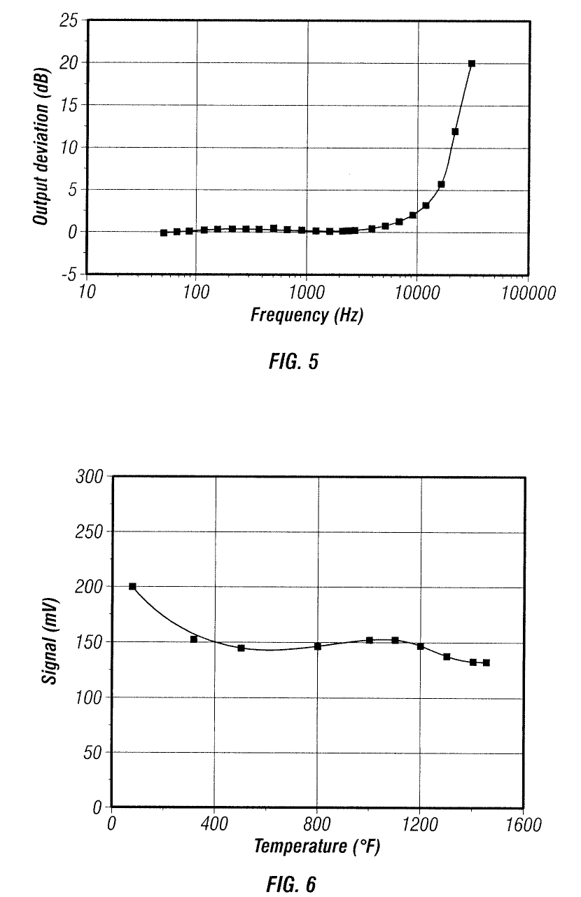

FIG. 5 is the frequency response of a sample acceleration sensor. The resonance frequency is over 30,000 Hz and the ±1 dB frequency is 30 to 7,000 Hz. The thermal response of the sensor is shown in FIG. 6. The sensor can work at 800° C. (1472° F.) and higher operation temperature up to 1000° C. is expected due to the thermal stability of AlN, ZnO, and Ta₂O₅ films.

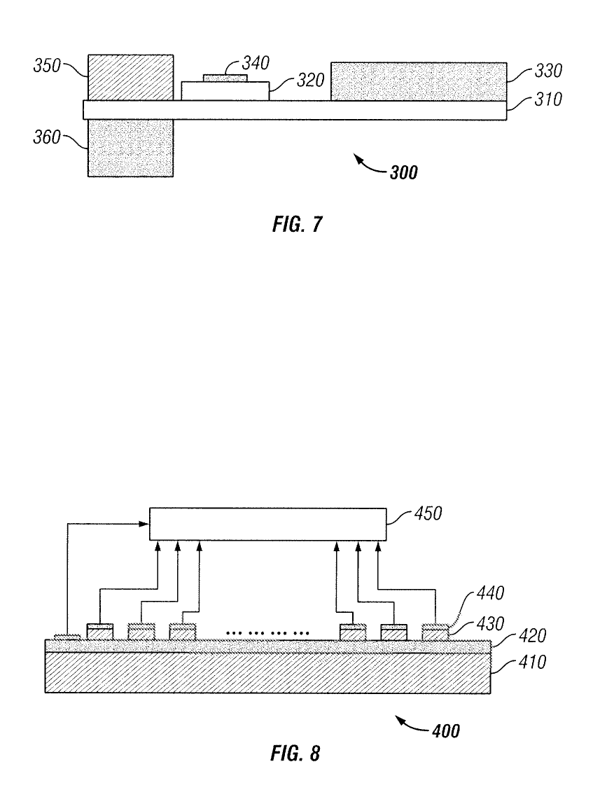

In one embodiment of the present invention, cantilever-type accelerometers 300 can also be built with the etched or micromachined piezoelectric films coated on to metal substrates. As shown in FIG. 7, the bending beam 310 carrying the sensing element 320 are diced from the wafers. One end of the beam is fixed onto a base 360 with a clamp 350 and the other end is loaded with a mass 330. Charges are created between the beam 310 and the tope electrode 340 when the mass experience acceleration like vibration and shock. This kind of sensors has advantages of small foot print, low weight, and high output. All the hardware components are made of high temperature sustainable metals or alloys.

In another embodiment of the present invention, miniature or micro sensors and their arrays 400 are manufactured by wet or dry etching the aluminum nitride, zinc oxide films, or tantalum oxide, as illustrated in FIG. 8. The piezoelectric films 430 including aluminum nitride, zinc oxide, and tatalum oxide are coated on the substrate 410 that is pre-coated with an electrode layer 420. Then top electrode 440 is coated on to the piezoelectric film 430. By dry or wet etching, micro sensing elements are manufactured. By monitoring the charge or voltage created at the different sensing elements with charge amplifier or voltmeter 450, the stress and pressure and their distribution that the structural components experience in high temperature manufacturing and fluidic systems can be measured and evaluated.

The micro sensor arrays also provide a powerful approach for the high resolution ultrasound detection of high temperature manufacturing of precision components and parts and in-line health monitoring of engines.

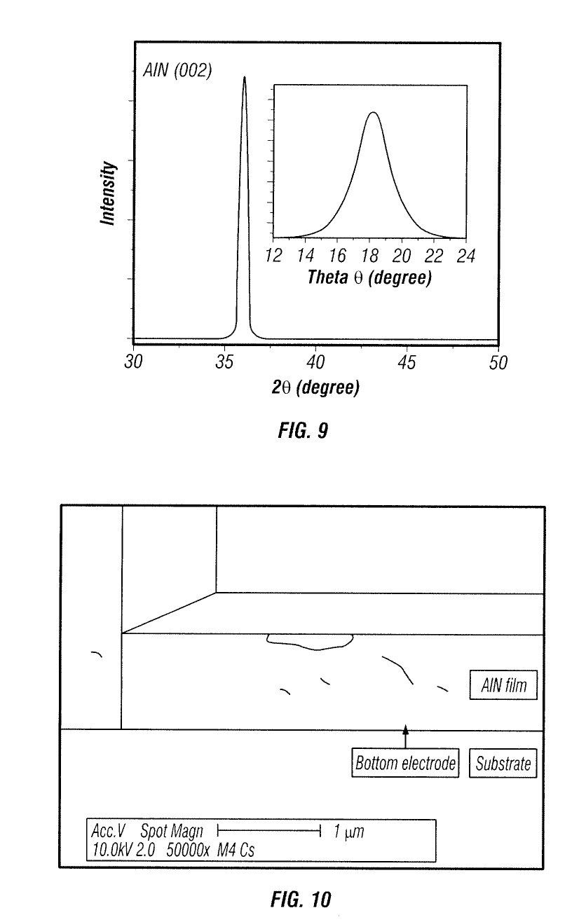

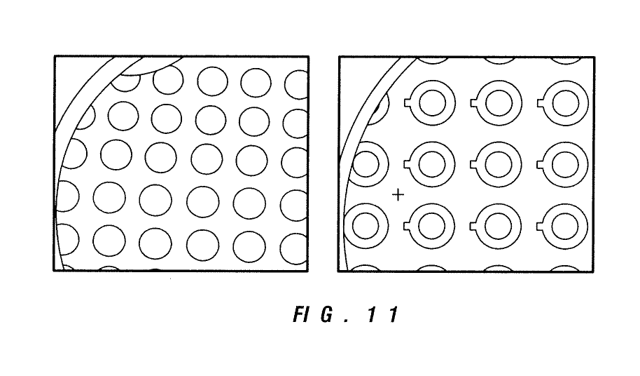

In one embodiment of the present invention, aluminum nitride films of 1 to 10 μm thick are deposited by reactive sputtering, CVD, MBE or the like onto substrates that include but are not limited to, silicon, sapphire, alumina ceramics, metals and alloys such as aluminum and stainless steels. Prior to the deposition, the substrates are highly polished and the non-conducting ones are coated with noble metals or alloys as bottom electrode. The crystallinity of the aluminum nitride films can be examined with X-ray diffractometer to confirm the preferred growth of the films so as to ensure optimal piezoelectric performance. As a sample, FIG. 9 shows the X-ray diffraction of AlN film on Si. The inset is the rocking curve of the diffraction. The films 002 are highly oriented. The cross-section of the films is shown in FIG. 10.

The films can be wet or dry etched into different patterns. FIG. 11 shows some circular and ring-type piezoelectric sensing elements. One of the wet etching processes is as follows. 1) Clean the AlN film/substrate with IPA (isoproponal alcohol) and blow dry with N₂. 2) Spin photoresist (Shipley 1827 for example) on to the film. 3) Bake the photoresist in oven at 95° C. for 20 to 30 min. 4) Expose the photoresist with ultra violet light through a photomask. 5) Develop the photoresist in developer MF 319 to remove the exposed area. 6) Transfer the developed patterns to another preheated MF319 solution (45° C. for example) to etch the AlN films. Examine the patterns till the exposed AlN films are removed and the bottom electrode is exposed.

While the invention has been described by way of examples and in terms of the specific embodiments, it is to be understood that the invention is not limited to the disclosed samples and embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A piezoelectric sensor, comprising:
a housing;
a diaphragm coupled to the housing;
a substrate body coupled to the diaphragm, the substrate body being coated with a wide band gap piezoelectric thin film, and
a connector for electrically connecting the film-coated substrate body with test electronics.

2. The sensor of claim 1, wherein the substrate is selected from the group consisting of silicon, sapphire, alumina ceramics, metals and alloys such as Inconel steels.

3. The sensor of claim 1, wherein the piezoelectric thin film is selected from the group consisting of aluminum nitride (AlN), zinc oxide (ZnO) and tantalum oxide (Ta₂O₅).

4. The sensor of claim 1, wherein the films can be etched or micro machined by wet or dry etching processing.

5. The sensor of claim 4, wherein one of the etchants for aluminum nitride and zinc oxide films is a solution containing trimethyl ammonium hydroxide.

6. The sensor of claim 1, wherein the films have a piezoelectric charge sensitivity of 1-10 pC/N and resistivity of up to 10¹³ Ω·cm.

7. The sensor of claim 1; wherein the films have a frequency response >30,000 Hz and the ±1 dB frequency is 30 to 7,000 Hz.

8. The sensor of claim 1; wherein the films have an operation temperature between 500-1000° C., preferably between 800-1000° C.

9. The sensor of claim 1, wherein the housing and diaphragm can withstand up to 1000° C.

10. The sensor of claim 1, wherein the sensor is configured to measure at least one of vibration, shock, pressure, acceleration, stress or force at high temperatures.

11. The sensor of claim 1, wherein the sensor is configured to operate at high temperatures up to 1000° C.

12. The sensor of claim 1, wherein the sensor is configured to operate at temperatures above 600° C.

13. The sensor of claim 1, wherein the sensor is configured to operate at temperatures above 700° C.

14. The sensor of claim 1, wherein the sensor is configured to operate at temperatures above 800° C.

15. The sensor of claim 1, wherein the sensor is configured to operate at temperatures above 900° C.

16. A piezoelectric pressure sensor, comprising;
a housing;
a diaphragm coupled to the housing;
a substrate body coupled to the diaphragm, the substrate body being coated with a wide band gap piezoelectric thin film, and
a connector for electrically connecting the film-coated substrate body with test electronics; whereby a first electrode and a second electrode are coupled to the wide band gap piezoelectric thin film.

17. The sensor of claim 16, wherein the substrate is selected from the group consisting of silicon, sapphire, alumina ceramics, metals and alloys such as Inconel steels.

18. The sensor of claim 16, wherein the piezoelectric thin film is selected from the group consisting of aluminum nitride (AIN), zinc oxide (ZnO) and tantalum oxide (Ta₂O₅).

19. The sensor of claim 16, wherein the films can be etched or micro machined by wet or dry etching processing.

20. The sensor of claim 19, wherein one of the etchants for aluminum nitride and zinc oxide films is a solution containing trimethyl ammonium hydroxide.

21. The sensor of claim 16, wherein the films have a piezoelectric charge sensitivity of 1-10 pC/N and resistivity of up to 10¹³ Ω·cm.

22. The sensor of claim 16; wherein the films have a frequency response >30,000 Hz and the ±1 dB frequency is 30 to 7,000 Hz.

23. The sensor of claim 16; wherein the films have an operation temperature between 500-1000° C., preferably between 800-1000° C.

24. The sensor of claim 16, wherein the housing and diaphragm can withstand up to 1000° C.

25. The sensor of claim 16, wherein the sensor is configured to measure at least one of vibration, shock, pressure, acceleration, stress or force at high temperatures.

26. The sensor of claim 16, wherein the sensor is configured to operate at high temperatures up to 1000° C.

27. The sensor of claim 16, wherein the sensor is configured to operate at temperatures above 600° C.

28. The sensor of claim 16, wherein the sensor is configured to operate at temperatures above 700° C.

29. The sensor of claim 16, wherein the sensor is configured to operate at temperatures above 800° C.

30. The sensor of claim 16, wherein the sensor is configured to operate at temperatures above 900° C.

31. A compression-mode piezoelectric acceleration sensor, comprising;
a mass;
a support structure;
a substrate body being coated with a wide band gap piezoelectric thin film, the substrate body being mounted to the support with a support member;
a first electrode and a second electrode coupled to the wide band gap piezoelectric thin film;
a first insulator positioned to insulate the wide band gap piezoelectric thin film and the mass. and
a second insulator positioned between the second electrode and the support member to isolate the wide band gap piezoelectric thin film and the crystal support.

32. The sensor of claim 31, wherein the substrate is selected from the group consisting of silicon, sapphire, alumina ceramics, metals and alloys such as Inconel steels.

33. The sensor of claim 31, wherein the piezoelectric thin film is selected from the group consisting of aluminum nitride (AIN), zinc oxide (ZnO) and tantalum oxide (Ta₂O₅).

34. The sensor of claim 31, wherein the films can be etched or micro machined by wet or dry etching processing.

35. The sensor of claim 34, wherein one of the etchants for aluminum nitride and zinc oxide films is a solution containing trimethyl ammonium hydroxide.

36. The sensor of claim 31, wherein the films have a piezoelectric charge sensitivity of 1-10 pC/N and resistivity of up to 10¹³ Ω·cm.

37. The sensor of claim 31; wherein the films have a frequency response >30,000 Hz and the +1 dB frequency is 30 to 7,000 Hz.

38. The sensor of claim 31; wherein the films have an operation temperature between 500-1000° C., preferably between 800-1000° C.

39. The sensor of claim 31, wherein the support member comprises a post and nut for mounting the substrate body to the support structure.

40. The sensor of claim 31, further comprising a housing made of a high temperature metal or alloy.

41. The sensor of claim 31, wherein the housing, the crystal support, mass, electrodes, insulators, and supporting material can withstand up to 1000° C.

42. The sensor of claim 31, wherein the sensor is configured to measure at least one of acceleration and shock at high temperatures.

43. The sensor of claim 31, wherein the sensor is configured to operate at high temperatures up to 1000° C.

44. The sensor of claim 31, wherein the sensor is configured to operate at temperatures above 600° C.

45. The sensor of claim 31, wherein the sensor is configured to operate at temperatures above 700° C.

46. The sensor of claim 31, wherein the sensor is configured to operate at temperatures above 800° C.

47. The sensor of claim 31, wherein the sensor is configured to operate at temperatures above 900° C.

48. A cantilever-type piezoelectric acceleration sensor, comprising
a beam of metal;
a base and a clamp coupled to a first end of said metal beam;
a mass loaded on a second end of said metal beam; and
a sensing element positioned between said base and said mass; wherein said sensing element is coated with wide band gap piezoelectric film and coupled to an electrode.

49. The sensor of claim 48, wherein the substrate is selected from high temperature alloys such as Inconel steels.

50. The sensor of claim 48, wherein the piezoelectric thin film is selected from the group consisting of aluminum nitride (AIN), zinc oxide (ZnO) and tantalum oxide (Ta₂O₅).

51. The sensor of claim 48, wherein the films can be etched or micro machined by wet or dry etching processing.

52. The sensor of claim 51, wherein one of the etchants for aluminum nitride and zinc oxide films is a solution containing trimethyl ammonium hydroxide.

53. The sensor of claim 48; wherein the films have piezoelectric charge sensitivity of 1-10 pC/N and resistivity of about 10¹³ Ω·cm.

54. The sensor of claim 48; wherein the films have a frequency response >30,000 Hz and the ±1 dB frequency is 30 to 7,000 Hz.

55. The sensor of claim 48; wherein the films have an operation temperature between 500-1000° C., preferably between 800-1000° C.

56. The sensor of claim 48, wherein the beam, mass, base, and clamp can withstand up to 1000° C.

57. The sensor of claim 48, wherein the sensor is configured to measure at least one of acceleration, vibration and shock at high temperatures.

58. The sensor of claim 48, wherein the sensor is configured to operate at high temperatures up to 1000° C.

59. The sensor of claim 48, wherein the sensor is configured to operate at temperatures above 600° C.

60. The sensor of claim 48, wherein the sensor is configured to operate at temperatures above 700° C.

61. The sensor of claim 48, wherein the sensor is configured to operate at temperatures above 800° C.

62. The sensor of claim 48, wherein the sensor is configured to operate at temperatures above 900° C.

63. A micro sensor array, comprising
a substrate coated with an electrode layer;
a wide band gap piezoelectric film applied to said electrode layer; wherein said film is etched to manufacture multiple micro sensing elements;
a top electrode coated on to said piezoelectric film; and
a charge amplifier or voltimeter connected to said micro sensing elements.

64. The sensor array of claim 63; wherein the substrate is selected from metals, ceramics and single crystals;

65. The sensor array of claim 63, wherein the piezoelectric thin film is selected from the group consisting of aluminum nitride (AIN), zinc oxide (ZnO) and tantalum oxide (Ta₂O₅).

66. The sensor of claim 63; wherein the films have piezoelectric charge sensitivity of 1-10 pC/N and resistivity of about 10¹³ Ω·cm.

67. The sensor of claim 63; wherein the films have a frequency response >30,000 Hz and the ±1 dB frequency is 30 to 7,000 Hz.

68. The sensor of claim 63; wherein the films have an operation temperature between 500-1000° C., preferably between 800-1000° C.

69. The sensor array of claim 63, comprising one or more sensing elements.

70. The sensor array of claim 69, wherein the one or more piezoelectric sensing elements are etched using echant materials, or micomachined form piezoelectric films of aluminum nitride, zinc oxide, or tantalum oxide.

71. The sensor array of claim 70; wherein one of the etchant materials is solution containing trimethyl ammonium hydroxide.

72. The sensor array of claim 63, wherein the dimension of each sensor element of the array ranges from micro level to millimeter level.

73. The sensor array of claim 63, wherein the sensor array can be used to measure the stress and its distributions.

74. The sensor array of claim 63; wherein the sensor array is used as an ultrasound emitter and receiver.

75. The sensor array of claim 63, wherein the sensor array is used in non-destructive tests to evaluate high temperature manufacturing processes and in-line engine health monitoring.

76. The sensor array of claim 63, wherein the sensor array is used for high resolution imaging in high temperature precision manufacturing and medical applications.

77. The sensor of claim 63, wherein the sensor is configured to operate at high temperatures up to 1000° C.

78. The sensor of claim 63, wherein the sensor is configured to operate at temperatures above 600° C.

79. The sensor of claim 63, wherein the sensor is configured to operate at temperatures above 700° C.

80. The sensor of claim 63, wherein the sensor is configured to operate at temperatures above 800° C.

81. The sensor of claim 63, wherein the sensor is configured to operate at temperatures above 900° C.
